(19) United States
(12) Patent Application Publication
(10) Pub. No.: US 2026/0299864 A1
(43) Pub. Date: Oct. 1, 2026

(54) MONITOR DESIGNATING DEVICE

(71) Applicant: FUJI CORPORATION, Chiryu (JP)

(72) Inventor: Shuhei MIZUTANI, Yatomi-shi (JP)

(73) Assignee: FUJI CORPORATION, Chiryu (JP)

(21) Appl. No.: 19/477,203

(22) PCT Filed: May 24, 2023
(86) PCT No.: PCT/JP2023/019235

§ 371 Date: Oct. 21, 2025

(51) Int. Cl. G06F 3/14; G06F 3/04817; G06F 3/0484

(52) U.S. Cl. CPC G06F 3/1423; G06F 3/04817; G06F 3/0484

(57) ABSTRACT

The monitor designating device includes multiple monitors and a designation section. The multiple monitors are configured to allow a worker to operate, on a screen, a board work machine configured to perform a predetermined board work on a board. The designation section allows the worker to designate, on the screen, a valid monitor that is at least one of the multiple monitors and has an operation right to operate the board work machine.

### TECHNICAL FIELD

The present description discloses a technique related to a monitor designating device.

### BACKGROUND ART

The mounting work device described in Patent Literature 1 includes an operation section. The operation section is provided at the front and rear of the mounting work device, and can be operated in a case where a worker gives an instruction or makes a selection. Specifically, a display device having a touch panel includes a priority changeover switch. In a case where the worker is performing work on the touch panel on a first side of the front and rear sides of the mounting work device, and the priority changeover switch on a second side thereof is operated, the valid touch panel is automatically switched from the touch panel on the first side to the touch panel on the second side, and it becomes possible to perform work using the touch panel on the second side.

In the production system described in Patent Literature 2, a component mounting system can be remotely operated by a tablet carried by a worker. Further, the worker can release the remote operation by operating a forced release button.

### CITATION LIST

### Patent Literature

Patent Literature 1: JP-A-2015-005631
Patent Literature 2: JP-A-2015-032808

### BRIEF SUMMARY

### Technical Problem

In a case where multiple monitors that allow a worker to operate the board work machine on a screen are provided, and an operation right to operate the board work machine is switched by a mechanical switch, switching failure of the operation right may occur due to aging deterioration of the mechanical switch. In addition, since a harness for connecting the mechanical switch and a control device is required, there is a possibility that manufacturing cost and maintenance cost are increased.

In view of such circumstances, the present description discloses a monitor designating device capable of designating, on a screen, a monitor having an operation right to operate a board work machine.

### Solution to Problem

The present description discloses a monitor designating device including multiple monitors and a designation section. The multiple monitors allow a worker to operate, on a screen, a board work machine that performs a predetermined board work on a board. The designation section allows the worker to designate, on the screen, a valid monitor that is at least one of the multiple monitors and has an operation right to operate the board work machine.

### Advantageous Effects

With the monitor designating device described above, the monitor having the operation right to operate the board work machine can be designated on the screen.

### BRIEF DESCRIPTION OF DRAWINGS

FIG. 1 is a configuration diagram showing a configuration example of a production line.

FIG. 2 is a plan view showing a configuration example of a component mounting device.

FIG. 3 is a block diagram showing an example of a control block of a monitor designating device.

FIG. 4 is a schematic diagram showing a display example of a monitor.

FIG. 5 is a schematic diagram showing another display example of a normal region.

### DESCRIPTION OF EMBODIMENTS

### 1. Embodiment

### 1-1. Configuration Example of Production Line WL0

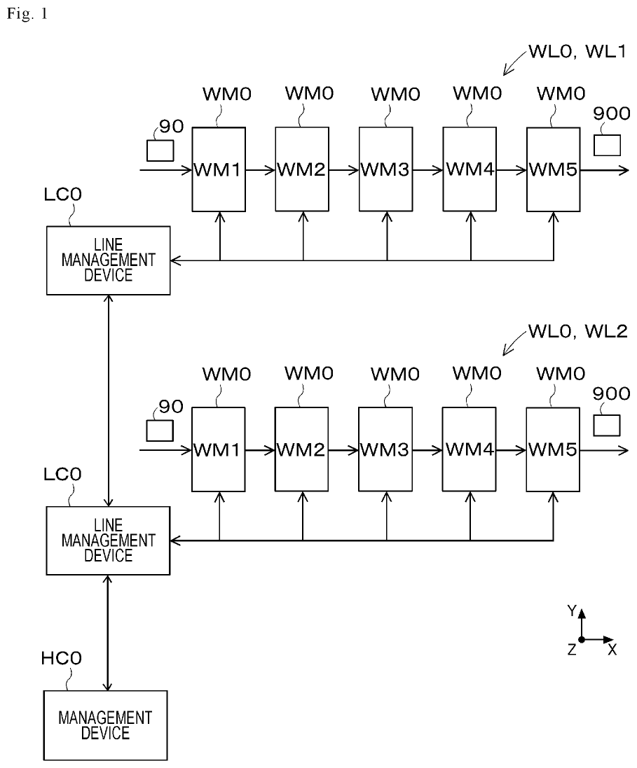

Monitor designating device 70 can be applied to at least one production line WL0 including at least one board work machine WM0. As shown in FIG. 1, a production facility of an embodiment includes two production lines WL0 including first production line WL1 and second production line WL2.

In each of two production lines WL0, at least one (five in the drawing) board work machine WM0 performs a predetermined board work on board 90. The type and number of board work machines WM0 constituting production line WL0 are not limited. As shown in FIG. 1, production line WL0 of the embodiment includes multiple board work machines WM0, which are printing machine WM1, printing inspector WM2, component mounting device WM3, reflow oven WM4, and visual inspector WM5, and board 90 is conveyed in order described above by a board conveyance device.

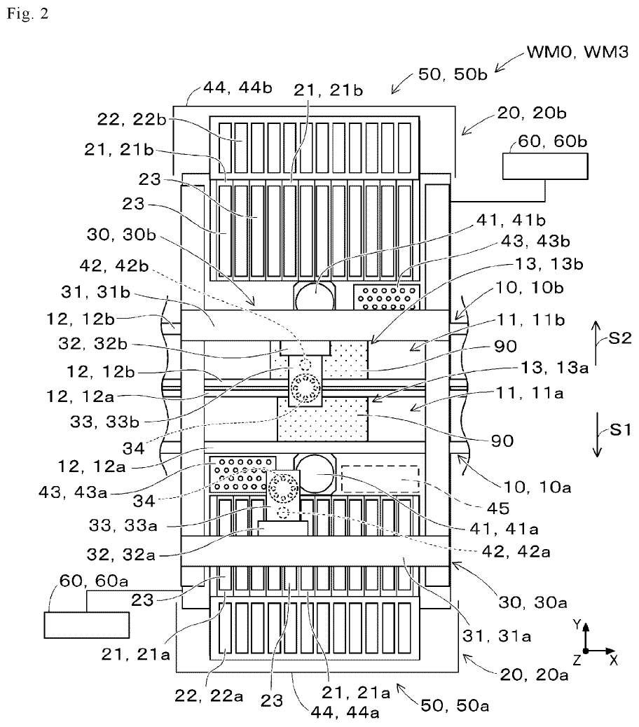

Printing machine WM1 prints solder on mounting positions of multiple components of board 90. Printing inspector WM2 inspects a printing state of the solder printed by printing machine WM1. As shown in FIG. 2, component mounting device WM3 mounts multiple components on board 90 on which the solder is printed by printing machine WM1. The number of component mounting device WM3 may be one or multiple. In a case where multiple component mounting devices WM3 are provided, multiple component mounting devices WM3 can share jobs to mount multiple components.

Reflow oven WM4 heats board 90 on which multiple components are mounted by component mounting device WM3, causes the solder to melt, and performs soldering. Visual inspector WM5 inspects mounting states or the like of multiple components which are mounted by component mounting device WM3. In this way, production line WL0 can convey board 90 in order using board work machine WM0 and execute a production process including an inspection process to produce product board 900. Production line WL0 may include board work machines WM0 such as a function inspector, a buffer device, a board supply device, a board reversing device, a shield mounting device, an adhesive applying device, and an ultraviolet ray irradiation device, as necessary.

At least one board work machine WM0, which constitutes production line WL0, and line management device LC0 are connected to be capable of communicating with each other via a communication section. Line management device LC0 and management device HC0 are connected to be capable of communicating with each other via the communication section. The communication section need only be capable of communicably connecting board work machine WM0 and line management device LC0, and line management device LC0 and management device HC0 via wired or wireless communication, and a communication method may take various methods.

In the embodiment, multiple board work machines WM0, line management device LC0, and management device HC0 constitute a local area network (LAN). As a result, multiple board work machines WM0 can communicate with each other via the communication section. In addition, multiple board work machines WM0 can communicate with line management device LC0 via the communication section. In addition, line management device LC0 and management device HC0 can communicate with each other via the communication section.

Line management device LC0 controls multiple board work machines WM0 constituting production line WL0 and monitors an operation status of production line WL0. Line management device LC0 stores various types of control data for controlling multiple board work machines WM0. Line management device LC0 transmits control data to each of multiple board work machines WM0. In addition, each of multiple board work machines WM0 transmits the operation status and a production status to line management device LC0. Management device HC0 manages at least one (two in FIG. 1) line management device LC0. For example, the operation status and the production status of board work machine WM0 acquired by line management device LC0 are transmitted to management device HC0 and managed, as necessary.

### 1-2. Configuration Example of Component Mounting Device WM3

Component mounting device WM3 mounts multiple components on board 90. As shown in FIG. 2, component mounting device WM3 of the embodiment includes two sets of component mounters 50, 50 each including board conveyance device 10, component supply device 20, component transfer device 30, part camera 41, board camera 42, nozzle station 43, and protection cover 44, and control device 45. The two sets of component mounters 50, 50 have a common structure and are disposed to face each other on the same base.

In the present description, for convenience of description, a side on which one of the two sets of component mounters 50, 50 is disposed (for example, the lower side of the paper surface of FIG. 2) is defined as first side S1. In addition, a side on which the other of the two sets of component mounters 50, 50 is disposed (for example, the upper side of the paper surface of FIG. 2) is defined as second side S2. Further, component mounter 50 disposed on first side S1 is indicated by component mounter 50a, and component mounter 50 disposed on second side S2 is indicated by component mounter 50b.

As described above, in component mounting device WM3 shown in FIG. 2, in order to identify the constituent members of the two sets of component mounters 50, 50, “a” is added to the end of the reference numeral of the constituent member disposed on first side S1, and “b” is added to the end of the reference numeral of the constituent member disposed on second side S2. In the present description, a conveyance direction of board 90 is defined as an X direction. In addition, a direction orthogonal to the conveyance direction (X direction) in the horizontal plane and in which the two sets of component mounters 50 face each other is defined as a Y direction. Further, a vertical direction orthogonal to the conveyance direction (X direction) and the facing direction (Y direction) is defined as a Z direction.

Board conveyance device 10 includes conveyance mechanisms 11 arranged side by side in the facing direction (Y direction). Conveyance mechanism 11 includes a pair of guide rails 12, 12 and conveyor belt 13. Each of the pair of guide rails 12 extends along the conveyance direction (X direction) of board 90, and can support the peripheral portion of board 90 placed and conveyed on conveyor belt 13. At least one of the pair of guide rails 12 is provided on the base to be movable along the facing direction (Y direction).

Board conveyance device 10 conveys board 90 in the conveyance direction (X direction). Board 90 is a circuit board, and an electronic circuit, an electric circuit, a magnetic circuit, and the like are formed. Board conveyance device 10 carries board 90 into component mounter 50 and positions board 90 at a predetermined position in component mounter 50. After a mounting process of multiple components by component mounter 50 is ended, board conveyance device 10 carries board 90 out of component mounter 50.

Component supply device 20 supplies components to be mounted on board 90. Component supply device 20 includes multiple slots 21 and multiple reel holding sections 22. Multiple slots 21 and multiple reel holding sections 22 are arranged along the conveyance direction (X direction) of board 90. Feeder 23 is detachably provided in each of multiple slots 21. Feeder 23 indexes by one pitch a carrier tape that accommodates components to supply the components so that the components can be picked up at a supply position located at a distal end side of feeder 23. Reel holding section 22 holds a reel on which the carrier tape is wound in an exchangeable manner. In addition, component supply device 20 can also supply an electronic component (for example, a lead component or the like) which is relatively large as compared with a chip component or the like in a state of being disposed on a tray.

Component transfer device 30 transfers the component supplied by component supply device 20 to a predetermined mounting position on board 90 carried into component mounter 50 by board conveyance device 10. Component transfer device 30 includes head drive device 31 and moving table 32. Head drive device 31 moves moving table 32 in the horizontal direction (conveyance direction (X direction) and facing direction (Y direction)) by the linear motion mechanism. Mounting head 33 is detachably (exchangeably) provided on moving table 32 by a clamp member.

Various tools are detachably (exchangeably) attached to mounting head 33. For example, suction nozzle 34 and a chuck are included in the tool. Suction nozzle 34 picks up and holds a component using supplied negative pressure air. A lifting and lowering position and an angle of suction nozzle 34 with respect to mounting head 33 and a supply state of the negative pressure air are controlled by control device 45 described later. Further, a chuck for clamping a component can be detachably (exchangeably) attached to mounting head 33.

As described above, component mounting device WM3 of the embodiment includes a facing robot in which two mounting heads 33 (mounting head 33a and mounting head 33b) are disposed to face each other. Movable regions of the two mounting heads 33 overlap each other, and the two mounting heads 33 are configured to be accessible to a side (in this case, second side S2) opposite to a side (for example, first side S1 on which mounting head 33a is provided) on which mounting heads 33 are provided. Therefore, the two mounting heads 33 can alternately work on the same board 90. Non-interference control is executed on the two mounting heads 33 by control device 45 so as not to interfere with each other in a region where the movable regions overlap each other.

As part camera 41 and board camera 42, well-known imaging devices can be used. Part camera 41 is fixed to a base of component mounting device WM3 such that the optical axis faces upward in a vertical direction (Z direction). Part camera 41 can image, for example, a component held by suction nozzle 34 from below. Board camera 42 is provided on moving table 32 of component transfer device 30 such that the optical axis faces downward in the vertical direction (Z direction). Board camera 42 can image board 90 or the like from above. Part camera 41 and board camera 42 perform imaging based on a control signal sent from control device 45. Image data of images captured by part camera 41 and board camera 42 are transmitted to control device 45.

Nozzle station 43 is provided in component mounting device WM3. For example, nozzle station 43 is detachably (exchangeably) installed on the base of component mounting device WM3. Nozzle station 43 is a tool station that accommodates various tools used for the board work of component mounting device WM3. Nozzle station 43 can detachably hold, for example, multiple suction nozzles 34.

In an exchange process of suction nozzle 34, nozzle station 43 holds suction nozzle 34 removed from mounting head 33 and holds suction nozzle 34 different from the aforementioned suction nozzle 34 in a removable manner. Accordingly, component mounting device WM3 can automatically exchange suction nozzle 34 according to the type of the component which is a mounting target, for example, during execution of the mounting process.

Protection cover 44 protects the worker. As shown in FIG. 2, protection cover 44 can cover the entire component mounter 50 including component supply device 20. For example, in a case where the worker performs work on component mounter 50a on first side S1, the worker opens and closes protection cover 44a on first side S1 and performs the work on component mounter 50a. Similarly, in a case where the worker performs work on component mounter 50b on second side S2, the worker opens and closes protection cover 44b on second side S2 and performs the work on component mounter 50b.

Control device 45 includes well-known computing device and storage device, and constitutes control circuit. Information, image data, and the like output from various sensors provided in component mounting device WM3 are input to control device 45. Control device 45 sends control signals to each device based on a control program, a predetermined mounting condition set in advance, and the like.

For example, control device 45 causes board camera 42 to image board 90 positioned by board conveyance device 10. Control device 45 performs image processing on the image captured by board camera 42, to recognize a positioning state of board 90. In addition, control device 45 causes, for example, suction nozzle 34 to pick up and hold the component supplied by component supply device 20, and causes part camera 41 to image the component held by suction nozzle 34. Control device 45 performs image processing on the image captured by part camera 41, to recognize a holding posture of the component.

Control device 45 moves suction nozzle 34 above a planned mounting position set in advance by a control program or the like. Further, based on the positioning state of board 90, the holding posture of the component, and the like, control device 45 corrects the planned mounting position to set the mounting position on which the component is actually mounted. The planned mounting position and the mounting position include a rotation angle in addition to a position (X coordinate and Y coordinate). Control device 45 corrects a target position (X coordinate and Y coordinate) and the rotation angle of suction nozzle 34 in accordance with the mounting position. Control device 45 lowers suction nozzle 34 at the corrected rotation angle at the corrected target position to mount the component on board 90.

Control device 45 repeats the pick-and-place cycle described above to execute the mounting process of mounting multiple components on board 90. A total time of a time required for a predetermined number of cycles of the pick-and-place cycle described above and a time required for carrying-in and carrying-out of board 90 corresponds to a cycle time per board 90.

### 1-3. Configuration Example of Monitor Designating Device 70

As shown in FIG. 2, board work machine WM0 includes multiple (two in the drawing) monitors 60, 60 that allow the worker to operate board work machine WM0 on the screen. For example, the operation right to operate board work machine WM0 is set to board work machine WM0 such that an operation using at least one monitor 60 of multiple (two) monitors 60, 60 and an operation using at least another one monitor 60 of multiple (two) monitors 60, 60 are not inconsistent with each other.

In the above form, in a case where the operation right to operate board work machine WM0 is switched, and for example, the operation right is switched by the mechanical switch, switching failure of the operation right may occur due to aging deterioration of the mechanical switch. In addition, since a harness for connecting the mechanical switch and control device 45 is required, there is a possibility that manufacturing cost and maintenance cost are increased.

Therefore, the production facility is provided with monitor designating device 70. Monitor designating device 70 includes multiple monitors 60, 60 and designation section 71. Accordingly, monitor designating device 70 can designate monitor 60 having the operation right to operate board work machine WM0 on screen 61. Monitor designating device 70 may include identification section 72. Designation section 71 and identification section 72 can be provided in various control devices and management devices. For example, at least one of designation section 71 and identification section 72 can be provided in the control device of board work machine WM0 (for example, control device 45 in component mounting device WM3).

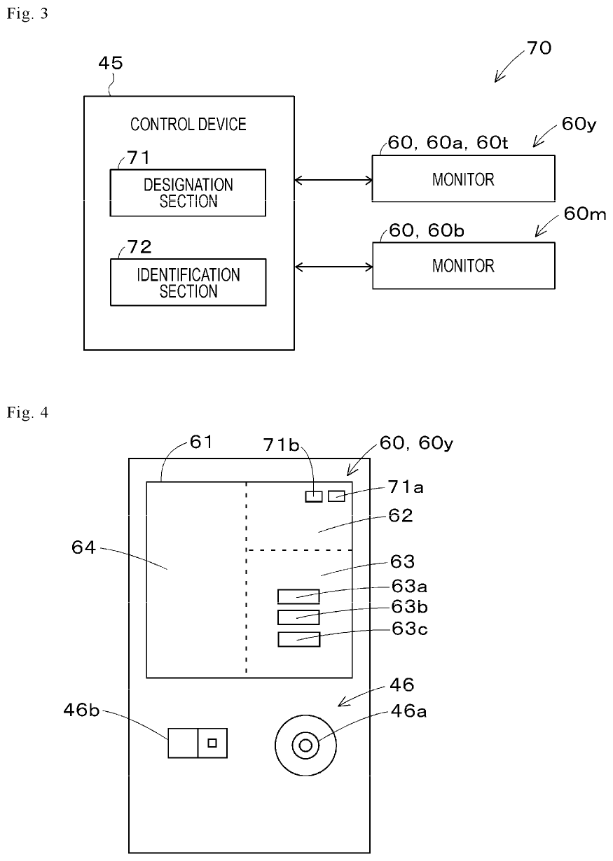

At least one of designation section 71 and identification section 72 may be provided in line management device LC0. At least one of designation section 71 and identification section 72 may be provided in management device HC0. At least one of designation section 71 and identification section 72 may be formed on a cloud. As shown in FIG. 3, in the embodiment, designation section 71 and identification section 72 are provided in control device 45 of component mounting device WM3. The matters described in the present description can be appropriately selected and applied. Further, the matters described in the present description can be appropriately combined.

### 1-3-1. Multiple Monitors 60 and Designation Section 71

Multiple (two in FIGS. 2 and 3) monitors 60, 60 may be any well-known monitors as long as the worker can operate board work machine WM0 on screen 61. For example, a monitor including a touch panel can be used as multiple (two) monitors 60, 60.

Multiple (two) monitors 60, 60 can be provided for each board work machine WM0. Multiple (two) monitors 60, 60 may be provided for each production line WL0. Multiple (two) monitors 60, 60 can also be provided in a portable terminal or the like carried by the worker. Multiple (two) monitors 60, 60 of the embodiment are provided for each board work machine WM0, and are provided in component mounting device WM3.

Specifically, board work machine WM0 of the embodiment includes component mounting device WM3. As described above, in component mounting device WM3, two component mounters 50 having a common structure and that mount components on board 90, are disposed to face each other on the same base. In addition, each of the two component mounters 50 includes at least one (one in FIGS. 2 and 3) monitor 60. For convenience of description, monitor 60 disposed on first side S1 is indicated by monitor 60a, and monitor 60 disposed on second side S2 is indicated by monitor 60b.

Designation section 71 allows the worker to designate valid monitor 60y on screen 61. In the present description, monitor 60 that is at least one of multiple (two in FIGS. 2 and 3) monitors 60, 60 and has the operation right to operate board work machine WM0 is referred to as valid monitor 60y. In addition, monitor 60 that is at least one of multiple (two in FIGS. 2 and 3) monitors 60, 60 and does not have the operation right to operate board work machine WM0 is referred to as invalid monitor 60m. In FIG. 3, for example, monitor 60a disposed on first side S1 is indicated by valid monitor 60y, and monitor 60b disposed on second side S2 is indicated by invalid monitor 60m.

Multiple (two in FIGS. 2 and 3) monitors 60, 60 and designation section 71 may take various forms as long as the worker can designate valid monitor 60y on screen 61. For example, on invalid monitor 60m, in a case where any operation on screen 61 by the worker is prohibited, switching of the operation right to operate board work machine WM0 needs to be performed in valid monitor 60y, which may complicate switching work of the operation right.

Therefore, as shown in FIG. 4, each of multiple (two) monitors 60, 60 may include normal region 62 and specific region 63. Normal region 62 is a region on screen 61, and is a region that is operable by the worker regardless of whether monitor 60 is valid monitor 60y. Specific region 63 is a region on screen 61 different from normal region 62, and is a region that is operable by the worker on valid monitor 60y. In the above form, designation section 71 may allow the worker to designate valid monitor 60y in normal region 62. Accordingly, the worker can designate valid monitor 60y on screen 61 regardless of whether monitor 60 to be operated is valid monitor 60y.

In addition, specific region 63 is a region that is operable by the worker on valid monitor 60y, and does not need to be displayed on invalid monitor 60m. Therefore, specific region 63 needs not to be displayed on invalid monitor 60m, but may be displayed on valid monitor 60y. As a result, in invalid monitor 60m, it is possible to prevent the worker from misunderstanding that there is a problem in a case where the worker cannot operate specific region 63 by mistake to operate specific region 63.

Specific region 63 can also be displayed on invalid monitor 60m to clearly indicate that the worker cannot operate. For example, specific region 63 can be displayed on invalid monitor 60m differently from the display in valid monitor 60y (for example, change of display color, addition of an icon of a circle with a diagonal line, or the like). Also in this form, the above misunderstanding can be prevented.

The worker can perform various operations on screen 61 in specific region 63 of valid monitor 60y. For example, in specific region 63, the worker can instruct board work machine WM0 at least one of the start of a board work, the shift to a power saving mode, the return from the power saving mode, and the stop of the board work. Specifically, as shown in FIG. 4, specific region 63 includes start icon 63a, power saving mode icon 63b, and stop icon 63c. In a case where the worker operates (touches) start icon 63a, the board work machine WM0 starts the board work.

In a case where the worker operates (touches) power saving mode icon 63b, the mode shifts from a normal mode to the power saving mode. In a case where the worker operates (touches) power saving mode icon 63b again, the mode returns from the power saving mode and shifts to the normal mode. In a case where the worker operates (touches) stop icon 63c, board work machine WM0 stops the board work. In this way, the worker can perform various operations on screen 61 in specific region 63 of valid monitor 60y to operate board work machine WM0.

As shown in FIG. 4, each of multiple (two) monitors 60, 60 can include display region 64. Display region 64 is a region that the worker cannot operate on screen 61, and board work machine WM0 and the like can display various types of information. For example, display region 64 can display the operation status and the production status of board work machine WM0, guidance for the worker, and the like.

As described above, designation section 71 can allow the worker to designate valid monitor 60y in normal region 62. Accordingly, the worker can designate valid monitor 60y on screen 61 regardless of whether monitor 60 to be operated is valid monitor 60y. However, for example, there is a case where it is desired to maintain the current designation of valid monitor 60y depending on the work status of the worker.

Therefore, as shown in FIG. 4, designation section 71 may display designation icon 71a and maintenance icon 71b on screen 61. Designation icon 71a is an icon for designating valid monitor 60y. Maintenance icon 71b is an icon for prohibiting designation to valid monitor 60y from invalid monitor 60m, and maintaining the current designation of valid monitor 60y.

Specifically, in a case where the worker operates (touches) designation icon 71a on first monitor 60, first monitor 60 is designated as valid monitor 60y. In this state, in a case where the worker operates (touches) designation icon 71a or maintenance icon 71b on second monitor 60 different from first monitor 60, second monitor 60 is designated as valid monitor 60y, and first monitor 60 is designated as invalid monitor 60m.

On the other hand, in a case where the worker operates (touches) maintenance icon 71b on first monitor 60, first monitor 60 is designated as valid monitor 60y, and the designation is maintained. Therefore, on second monitor 60 different from first monitor 60, even in a case where the worker operates (touches) designation icon 71a or maintenance icon 71b, the designation of valid monitor 60y is maintained in first monitor 60, and the designation of invalid monitor 60m is maintained in second monitor 60.

In this state, in a case where the worker operates (touches) designation icon 71a on first monitor 60, first monitor 60 releases the maintenance of the designation of valid monitor 60y. Therefore, in a case where the worker operates (touches) designation icon 71a or maintenance icon 71b on second monitor 60, second monitor 60 is designated as valid monitor 60y, and first monitor 60 is designated as invalid monitor 60m. In addition, the above description of first monitor 60 and second monitor 60 can be similarly applied to a form in which first monitor 60 and second monitor 60 are switched with each other.

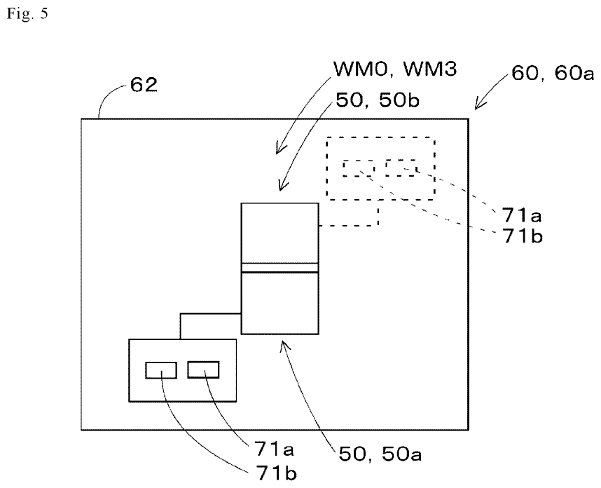

As the number of monitors 60 increases, it may be more difficult for the worker to recognize the position of monitor 60 to be designated as valid monitor 60y in board work machine WM0. Therefore, as shown in FIG. 5, designation section 71 can display an image simulating the disposition of multiple (two) monitors 60, 60 in board work machine WM0 on screen 61 to allow the worker to designate valid monitor 60y.

FIG. 5 shows another display example of normal region 62, and normal region 62 is shown in an enlarged manner. This drawing shows that an image simulating the disposition of multiple (two) monitors 60, 60 in component mounting device WM3 shown in FIG. 2 is displayed in normal region 62. Normal region 62 shown in FIG. 5 indicates, for example, normal region 62 of monitor 60a disposed on first side S1. An icon (rectangle) of monitor 60 indicated by a solid line in the drawing indicates monitor 60a disposed on first side S1. An icon (rectangle) of monitor 60 indicated by a broken line in the drawing indicates monitor 60b disposed on second side S2.

Since the drawing shows normal region 62 of monitor 60a disposed on first side S1, the icon (rectangle) of monitor 60a disposed on first side S1 is highlighted as compared with the icon (rectangle) of monitor 60b disposed on second side S2. In addition, designation icon 71a and maintenance icon 71b are displayed on the icon (rectangle) of monitor 60a disposed on first side S1, and the worker can operate (touch) designation icon 71a or maintenance icon 71b. Accordingly, the worker can easily recognize the position of monitor 60 (monitor 60a in the above example) to be designated as valid monitor 60y in component mounting device WM3. The above description of monitor 60a can be similarly applied to monitor 60b.

As described above, designation section 71 allows the worker to designate valid monitor 60y on screen 61, so that the mechanical switch for switching the operation right to operate board work machines WM0 can be omitted. In addition, in specific region 63, the worker can instruct board work machine WM0 to perform a predetermined operation, and the mechanical switch for the predetermined operation can be omitted. However, in the operation of board work machine WM0, some mechanical switches cannot be omitted due to standards.

Therefore, as shown in FIG. 4, board work machine WM0 may include mechanical switch 46 that allows the worker to perform a predetermined operation on board work machine WM0 regardless of the presence or absence of the operation right. Mechanical switch 46 may take various forms as long as mechanical switch 46 can mechanically switch an instruction to board work machine WM0. For example, mechanical switch 46 may include emergency stop switch 46a for emergently stopping driven board work machine WM0.

The worker can emergently stop driven board work machine WM0 by pressing emergency stop switch 46a. In a case where emergency stop switch 46a is pressed by the worker, board work machine WM0 immediately stops the board work being executed. In a case where the worker operates (touches) stop icon 63c in specific region 63, board work machine WM0 stops the board work. In this case, board work machine WM0 stops the board work after a predetermined pick-and-place cycle being executed is ended.

As shown in FIG. 4, mechanical switch 46 may include at least one mechanical switch 46b in addition to emergency stop switch 46a. Mechanical switch 46b can be used for any operation of board work machine WM0. For example, in a case where mechanical switch 46b is pressed by the worker, board work machine WM0 can start any board work, and can interrupt or end any board work.

In a case where the worker performs a predetermined work on board work machine WM0, the worker is highly likely to operate board work machine WM0 using monitor 60 disposed on the side on which the predetermined work is performed. Therefore, in a case where the worker performs the predetermined work on board work machine WM0, designation section 71 can designate, as valid monitor 60y, corresponding monitor 60t disposed on the side on which the predetermined work is performed among multiple (two) monitors 60, 60.

The predetermined work is not limited. For example, at least one of attachment and detachment of component supply device 20 that supplies the component in component mounter 50 that mounts the component on board 90, and opening and closing of protection cover 44 that protects the worker is included in the predetermined work. As shown in FIG. 2, for example, in a case where component supply device 20a disposed on first side S1 is attached or detached, monitor 60a disposed on first side S1 is highly likely to be used. Similarly, in a case where protection cover 44a disposed on first side S1 is opened or closed, monitor 60a disposed on first side S1 is highly likely to be used.

In any case, corresponding monitor 60t is monitor 60a disposed on first side S1. Therefore, designation section 71 designates monitor 60a disposed on first side S1, which is corresponding monitor 60t, as valid monitor 60y. Similarly, in a case where component supply device 20b disposed on second side S2 is attached or detached, designation section 71 designates monitor 60b disposed on second side S2, which is corresponding monitor 60t, as valid monitor 60y. In a case where protection cover 44b disposed on second side S2 is opened or closed, designation section 71 designates monitor 60b disposed on second side S2, which is corresponding monitor 60t, as valid monitor 60y.

Component mounting device WM3 includes a sensor that detects attachment and detachment of component supply device 20, and opening and closing of protection cover 44. Designation section 71 can recognize attachment and detachment of component supply device 20, and opening and closing of protection cover 44 based on a detection result of the sensor. In this way, in a case where the worker performs the predetermined work on board work machine WM0, designation section 71 can automatically designate valid monitor 60y by simulating the designation of valid monitor 60y by the worker.

### 1-3-2. Identification Section 72

As shown in FIG. 1, a production facility of an embodiment includes two production lines WL0 including first production line WL1 and second production line WL2. For example, a worker in charge of first production line WL1 and a worker in charge of second production line WL2 may be distinguished from each other. In this case, it is not preferable that the worker in charge of first production line WL1 operates board work machine WM0 of second production line WL2. Similarly, it is not preferable that the worker in charge of second production line WL2 operates board work machine WM0 of first production line WL1.

Therefore, identification section 72 identifies the worker. Identification section 72 may take various forms as long as identification section 72 can identify the worker. For example, identification section 72 can read an identification card carried by the worker using a reading device and acquire identification information capable of identifying the worker. Identification section 72 can also identify the worker by biometric authentication such as fingerprint authentication or face authentication.

Designation section 71 permits designation of valid monitor 60y in a case where the worker identified by identification section 72 is a predetermined worker who can designate valid monitor 60y, and prohibits the designation of valid monitor 60y in a case where the worker identified by identification section 72 is not the predetermined worker. Accordingly, designation section 71 can allow the predetermined worker to designate valid monitor 60y and prohibit the designation of valid monitor 60y by a worker who is not the predetermined worker.

### 2. Other Forms

As shown in FIG. 2, board work machine WM0 of the embodiment includes component mounting device WM3 in which two component mounters 50 having a common structure and that mount components on board 90, are disposed to face each other on the same base. In addition, each of the two component mounters 50 includes at least one (one in the drawing) monitor 60.

However, board work machine WM0 and multiple monitors 60 are not limited to the above-described form. For example, component mounting device WM3 can include one component mounter 50 that mounts a component on board 90. Further, one component mounting device WM3 can be provided with at least one monitor 60. Production line WL0 can include multiple component mounting devices WM3 having a common structure, and can include multiple monitors 60.

Multiple component mounting devices WM3 can be arranged along the conveyance direction (X direction) of board 90. In this case, monitor 60 provided in first component mounting device WM3 can be used to operate second component mounting device WM3. Monitor 60 provided in first component mounting device WM3 corresponds to valid monitor 60y, and monitor 60 provided in second component mounting device WM3 corresponds to invalid monitor 60m. Board work machine WM0 is not limited to component mounting device WM3. Board work machine WM0 may be the various board work machines WM0 described above such as printing machine WM1.

### 3. Example of Effects of Embodiments

With monitor designating device 70, monitor 60 having the operation right to operate board work machine WM0 can be designated on screen 61.

### REFERENCE SIGNS LIST

20: component supply device, 44: protection cover, 46: mechanical switch,
50: component mounter, 60: monitor, 60y: valid monitor,
60m: invalid monitor, 60t: corresponding monitor, 61: screen,
62: normal region, 63: specific region, 70: monitor designating device,
71: designation section, 71a: designation icon, 71b: maintenance icon,
72: identification section, 90: board, WM0: board work machine,
WM3: component mounting device

1. A monitor designating device comprising:
multiple monitors configured to allow a worker to operate, on a screen, a board work machine configured to perform a predetermined board work on a board; and
a designation section configured to allow the worker to designate, on the screen, a valid monitor that is at least one of the multiple monitors and has an operation right to operate the board work machine.

2. The monitor designating device according to claim 1, wherein
each of the multiple monitors includes
a normal region that is a region on the screen and is operable by the worker regardless of whether the monitor is the valid monitor, and
a specific region that is a region on the screen different from the normal region and is operable by the worker on the valid monitor, and
the designation section allows the worker to designate the valid monitor in the normal region.

3. The monitor designating device according to claim 2, wherein the specific region is not displayed on an invalid monitor that is at least one of the multiple monitors and does not have the operation right, and is displayed on the valid monitor.

4. The monitor designating device according to claim 2, wherein in the specific region, the worker is able to instruct the board work machine to perform at least one of a start of the board work, a shift to a power saving mode, a return from the power saving mode, and a stop of the board work.

5. The monitor designating device according to claim 1, wherein in a case where the worker performs a predetermined work on the board work machine, the designation section designates, as the valid monitor, a corresponding monitor disposed on a side on which the predetermined work is performed among the multiple monitors.

6. The monitor designating device according to claim 5, wherein the predetermined work is at least one of attachment and detachment of a component supply device configured to supply components in a component mounter configured to mount the components on the board, and opening and closing of a protection cover configured to protect the worker.

7. The monitor designating device according to claim 1, wherein
the designation section displays, on the screen,
a designation icon for designating the valid monitor, and
a maintenance icon for prohibiting designation to the valid monitor from an invalid monitor that is at least one of the multiple monitors and does not have the operation right, and maintaining current designation of the valid monitor.

8. The monitor designating device according to claim 1, wherein the board work machine includes a mechanical switch configured to allow the worker to perform a predetermined operation on the board work machine regardless of presence or absence of the operation right.

9. The monitor designating device according to claim 1, further comprising:
an identification section configured to identify the worker, wherein
the designation section permits designation of the valid monitor in a case where the worker identified by the identification section is a predetermined worker who is able to designate the valid monitor, and prohibits the designation of the valid monitor in a case where the worker identified by the identification section is not the predetermined worker.

10. The monitor designating device according to claim 1, wherein
the board work machine is a component mounting device in which two component mounters that have a common structure and that are configured to mount components on the board, are disposed to face each other on the same base, and
each of the two component mounters includes at least one monitor.
